(19) United States
(12) Patent Application Publication
(10) Pub. No.: US 2026/0333626 A1
(43) Pub. Date: Oct. 22, 2026

(54) MULTIPLE CRYOGENIC HEAT SINK ROTATION

(71) Applicant: The Boeing Company, Arlington, VA (US)

(72) Inventors: Mark Edward NOWAKOWSKI, Long Beach, CA (US); Ian M. DAYTON, Middle River, MD (US); Rudolph MAGYAR, Fulton, MD (US)

(21) Appl. No.: 19/185,426

(22) Filed: Apr. 22, 2025

(51) Int. Cl. H05K 7/20; F28F 13/00

(52) U.S. Cl. CPC H05K 7/20272; F28F 13/00; H05K 7/20281; F28F 2013/008

(57) ABSTRACT

In some implementations, a cryogenic cooling system may include a device, a first cooling circuit thermally connected to the device and configured to perform cooling of the device, a second cooling circuit, a plurality of high mass-heat capacity (HMHC) blocks, a first set of heat switches configured to thermally connect the plurality of HMHC blocks to the device and to thermally disconnect the plurality of HMHC blocks from the device, and a second set of heat switches configured to thermally connect the plurality of HMHC blocks to the second cooling circuit and to thermally disconnect the plurality of HMHC blocks from the second cooling circuit.

### FIELD

The present disclosure relates generally to cryogenic cooling and to cryogenic cooling of a device using multiple cryogenic heat sinks.

### BACKGROUND

“Cryogenic cooling” refers to a cooling process that reduces temperatures to extremely low levels. Cryogenic cooling is used to cool devices, such as integrated circuits (ICs) and/or sensors, during operation of such devices to enable extended high-power operation and high computing speed. Cryogenic cooling circuits typically use direct immersion in liquid cryogens, such as helium or nitrogen, a liquid cryogen (e.g., helium or nitrogen) heat exchanger, or a helium pulse tube for cooling of a device.

### SUMMARY

An embodiment of the present disclosure provides a cryogenic cooling system, comprising: a device; a first cooling circuit thermally connected to the device and configured to perform cooling of the device; a second cooling circuit; a plurality of high mass-heat capacity (HMHC) blocks; a first set of heat switches configured to thermally connect the plurality of HMHC blocks to the device and to thermally disconnect the plurality of HMHC blocks from the device; and a second set of heat switches configured to thermally connect the plurality of HMHC blocks to the second cooling circuit and to thermally disconnect the plurality of HMHC blocks from the second cooling circuit.

Another embodiment of the present disclosure provides a method of cryogenic cooling, comprising: performing, by a first cooling circuit, cooling of a device; connecting a plurality of HMHC blocks to a second cooling circuit to cool the plurality of HMHC blocks; connecting, at a first time, one or more first HMHC blocks to the device to manipulate the cooling of the device; disconnecting, at a second time, the one or more first HMHC blocks from the device; and connecting, at the second time, one or more second HMHC blocks, of the plurality of HMHC blocks, to the device to manipulate the cooling of the device.

Yet a further embodiment of the present disclosure provides a cryogenic cooling system, comprising: a first cooling circuit thermally connectable to a device and configured to perform cooling of the device; a second cooling circuit; a plurality of cryogenic heat sinks thermally connectable to the device via respective first heat switches, and thermally connectable to the second cooling circuit via respective second heat switches; and a controller configured to: control the respective first heat switches and the respective second heat switches such that one or more cryogenic heat sinks, of the plurality of cryogenic heat sinks, are in an active state in which the one or more cryogenic heat sinks are thermally connected to the device and disconnected from the second cooling circuit, and one or more other cryogenic heat sinks, of the plurality of cryogenic heat sinks, are in an inactive state in which the one or more other cryogenic heat sinks are thermally disconnected from the device and connected to the second cooling circuit, and control the respective first heat switches and the respective second heat switches to rotate which of the plurality of cryogenic heat sinks are in the active state and which of the plurality of cryogenic heat sinks are in the inactive state.

The features, functions, and advantages described herein can be achieved independently in various implementations or can be combined in other implementations, further details of which are shown in the drawings and described below.

### BRIEF DESCRIPTION OF THE DRAWINGS

FIGS. 1A-1B are diagrams of an example implementation associated with multiple cryogenic heat sink rotation.

FIG. 2 is a diagram of an example implementation associated with multiple cryogenic heat sink rotation.

FIG. 3 is a diagram of an example implementation associated with multiple cryogenic heat sink rotation.

FIG. 4 is a diagram of example components of a device associated with multiple cryogenic heat sink rotation.

FIG. 5 is a flowchart of an example process associated with multiple cryogenic heat sink rotation.

### DETAILED DESCRIPTION

The following detailed description of example implementations refers to the accompanying drawings. The same reference numbers in different drawings identify the same or similar elements.

Devices, such as integrated circuits and/or sensors, among other examples, produce heat during operation of such devices. The amount of heat produced by an IC device increases when the IC device is operating under heavy loads. The heat produced during operation of a device can result in damage or a reduction of functionality of the device. For example, heat is destructive to IC materials, and thus can damage an IC device.

Devices are often cooled during operation of such devices to enable extended high-power operation. In some cases, cryogenic cooling systems are used for cryogenic cooling of devices during operation of the devices. Cryogenic cooling systems typically use direct immersion in liquid cryogens (e.g., helium or nitrogen), a liquid cryogen heat exchanger, or a helium pulse tube for cooling of a device. While such cryogenic cooling techniques are often sufficient to cool a device down to a desired temperature, in some cases, the device, when fully operational, exceeds the cooling capabilities of the cryogenic cooling technique being used to cool the device. That is, although current cryogenic cooling systems can produce adequate cooling to cool a device to a base temperature, when an additional heat load is added (e.g., due to heat generated by the device being cooled), current cryogenic cooling systems are unable to account for the additional heat load and the base temperature rises as a result. This rise in the base temperature during operation of a device can cause a decrease in performance of the device and/or damage to the device.

In some implementations described herein, a cryogenic cooling system includes a first cooling circuit thermally connected to a device to perform cooling of the device, a second cooling circuit, and a plurality of high mass-heat capacity (HMHC) blocks. The cryogenic cooling system further includes a first set of heat switches configured to thermally connect the plurality of HMHC blocks to the device and to thermally disconnect the plurality of HMHC blocks from the device, and a second set of heat switches configured to thermally connect the plurality of HMHC blocks to the second cooling circuit and thermally disconnect the plurality of HMHC blocks from the second cooling circuit. The second set of heat switches enables individual HMHC blocks to be selectively thermally connected to the second cooling circuit to cool the HMHC blocks. The first set of heat switches enables individual HMHC blocks to be selectively thermally connected to the device to manipulate (e.g., boost) the cooling of the device. That is, the HMHC blocks may be cooled by the second cooling circuit, and then thermally connected to the device to act as cryogenic heatsinks to boost (or otherwise manipulate) the cooling of the device performed by the first cooling circuit. As a result, the cryogenic cooling system enables the controlled introduction of one or more precooled heat sinks into thermal connectivity with the device, providing additional cooling when needed, while also enabling greater control of the cooling (or heating) rate of the device. In this way, the cryogenic cooling system provides additional cooling power to a cryogenic cooling circuit connected to the device, thus preventing a decrease in performance of the device and/or damage to the device due to heat, during operation of the device, that exceeds a cooling capacity of the cryogenic cooling circuit.

Some implementations described herein enable a method of rotation or cycling which of the plurality of HMHC blocks are thermally connected to the device to actively manipulate (e.g., boost) the cooling of the device, and which of the plurality of HMHC blocks are thermally connected to the second cooling circuit. For example, a controller controls the first set of heat switches and the second set of heat switches to cycle which of the plurality of HMHC blocks are thermally connected to the device and which of the HMHC blocks are thermally connected to the second cooling circuit. This method of rotating or cycling the HMHC blocks that are thermally connected to the device enables the cryogenic cooling system to cycle cooled heat sinks (e.g., HMHC blocks) as needed to persist the additional cooling as long as necessary and/or boost the cooling further by thermally connecting multiple cooled heat sinks to the device simultaneously. In some implementations, the HMHC blocks that are thermally connected to the device may be selected to create a thermal gradient across regions of the device, which can achieve novel physics phenomena, such as thermoelectric effects, or optimized temperatures across different regions of the device.

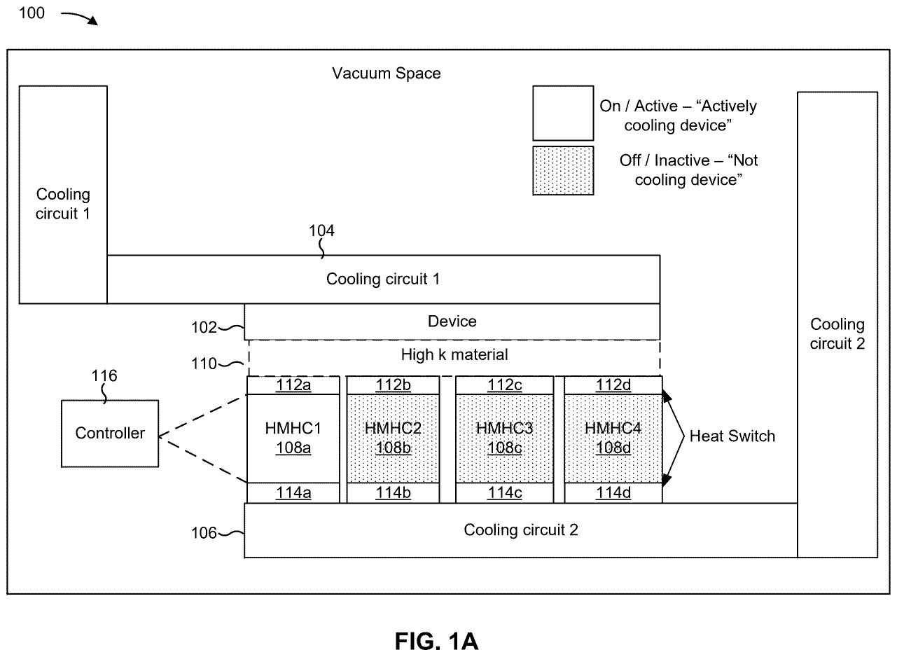

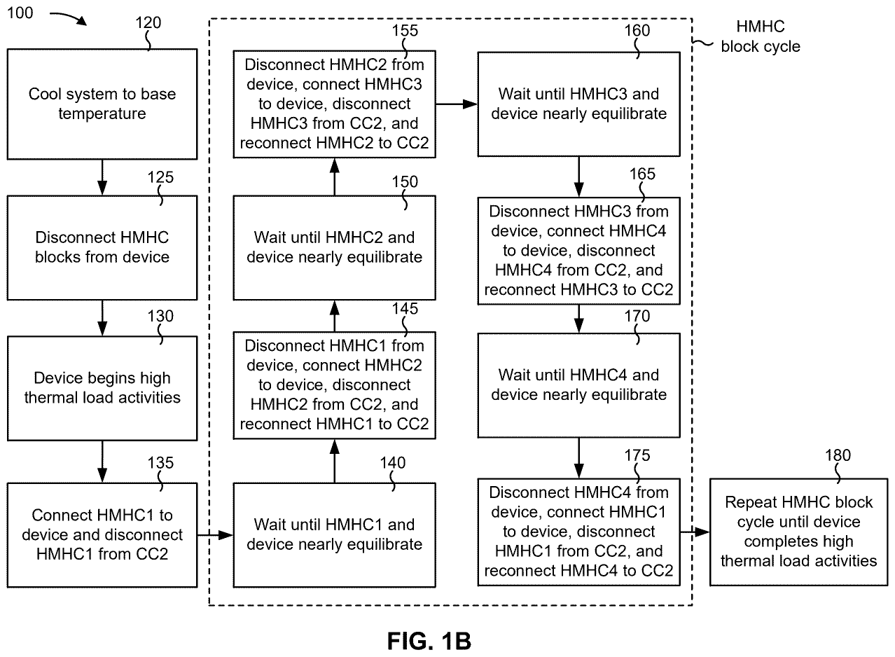

FIGS. 1A-1B are diagrams of an example implementation 100 associated with multiple cryogenic heat sink rotation. As shown in FIGS. 1A-1B, example implementation 100 includes a cryogenic cooling system and a device 102. The device 102 may be any device that operates, or includes one or more components that operate, at cryogenic temperatures. In some implementations, the device 102 may be, or include, an IC (e.g., a complementary metal-oxide semiconductor (CMOS) IC), an IC device (e.g., a device including one or more ICs), a cryogenic circuit, a semiconductor, a sensor (e.g., a sensor associated with a super-conducting technology), or a quantum computer, among other examples.

The cryogenic cooling system is configured to perform cooling of the device 102 to cryogenic temperatures. For example, the cryogenic cooling system may be configured to cool the device 102 to approximately a 4 Kelvin (K) or a milli-Kelvin (mK) temperature (explained below). As shown in FIG. 1A, the cryogenic cooling system includes a first cooling circuit 104, a second cooling circuit 106, a plurality of HMHC blocks 108, a thermally conductive material 110 (shown as “High k material”), a first set of heat switches 112, a second set of heat switches 114, and a controller 116. The cryogenic cooling system includes a vacuum space, in which the device 102 is cooled. The first cooling circuit 104, the second cooling circuit 106, the HMHC blocks 108, the thermally conductive material 110, the first set of heat switches 112, and the second set of heat switches 114 are included in the vacuum space. In some implementations, the controller 116 is also included in the vacuum space (e.g., as shown in FIG. 1A). In some other implementations, the controller 116 is not included in the vacuum space.

The cryogenic cooling system includes multiple cooling circuits, including at least the first cooling circuit 104 and the second cooling circuit 106. In some implementations, the cooling circuits (e.g., the first cooling circuit 104, the second cooling circuit 106, and/or one or more other cooling circuits) may be 4K or mK cooling circuits. A 4K cooling circuit is a cooling circuit or refrigeration unit capable of cooling a payload to approximately 4 K. An mK cooling circuit is a cooling circuit or refrigeration unit capable of cooling a payload to a mK range (e.g., approximately 10 mK-300 mK). In some implementations, the cooling circuits may be or include dilution refrigeration cooling circuits, adiabatic demagnetization refrigeration (ADR) cooling circuits, other types of cooling circuits, or a combination thereof. In some examples, a cooling circuit (e.g., the first cooling circuit 104, the second cooling circuit 106, or another cooling circuit) may cool a payload thermally connected to the cooling circuit using direct immersion in liquid cryogens (e.g., helium or nitrogen), a liquid cryogen heat exchanger, one or more helium pulse tubes, or a combination thereof.

The first cooling circuit 104 is thermally connected to the device 102. “Thermally connected” refers to two components being directly connected or connected via one or more other components or materials (e.g., one or more components or materials with a high thermal conductivity) that allow heat to be transferred between the two components. As shown in FIG. 1A, in some implementations, the first cooling circuit 104 is thermally connected to a first surface of the device 102. The first cooling circuit 104 is configured to perform cooling (e.g., cryogenic cooling) of the device 102. For example, the first cooling circuit 104 may perform cooling of the device 102 using direct immersion of the device 102 in liquid cryogens, a liquid cryogen heat exchanger, one or more helium pulse tubes, or a combination thereof.

The cryogenic cooling system includes multiple HMHC blocks 108. For example, as shown in FIG. 1A, the cryogenic cooling system includes a first HMHC block 108a, a second HMHC block 108b, a third HMHC block 108c, and a fourth HMHC block 108d. In other implementations, the cryogenic cooling system may include more or fewer HMHC blocks 108. Each HMHC block 108 is a block of an HMHC material with a product of mass (m)*heat capacity (C) that satisfies (e.g., is greater than or equal to) a mass-heat capacity threshold. In some implementations, the mass-heat capacity threshold may be 2000 J/K (Joules/Kelvin). In this case, for each HMHC block 108, m*C≥2000 J/K. An HMHC material is a material with a high heat capacity (C) (e.g., a high mass heat capacity). That is, the HMHC material is a material with a mass heat capacity that satisfies (e.g., is greater than or equal to) a mass heat capacity threshold. In some implementations, the mass heat capacity threshold may be 0.5 J/gK (Joules/(gram·Kelvin)). In this case, the HMHC blocks are blocks of material with a mass heat capacity greater than or equal to 0.5 J/gK. In some other implementations, the mass heat capacity threshold may be another value (e.g., 1.0 J/gK, 1.5 J/gK, or 2.0 J/gK). In some examples, the HMHC material included in the HMHC blocks 108 may be a solid or a liquid. In an example in which the HMHC material is a liquid, the HMHC block 108 may include the HMHC material sealed in a solid (e.g., steel or another metal) container. In some examples, the HMHC material included in the HMHC blocks 108 may be a metal (e.g., titanium, sodium, lithium, aluminum, or magnesium, among other examples), silicon, graphite, paraffin wax, polyethylene, glass, methanol, ammonia, or water (e.g., in a perfectly sealed steel container), among other examples. Additionally, or alternatively, in some examples, an HMHC block 108 may include an HMHC material that is a gas (e.g., helium or hydrogen, among other examples), possibly in combination with another material (for example, a gas trapped in channels within a sealed solid (e.g., steel) container).

The thermally conductive material 110 connects the device 102 to the first set of heat switches 112. As shown in FIG. 1A, in some implementations, the thermally conductive material 110 is connected to a second surface of the device 102. For example, the second surface of the device 102 may be opposite the first surface of the device 102 that is connected to the first cooling circuit 104. The thermally conductive material 110 is a material with a high thermal conductivity (k), such as copper or gold, among other examples.

The first set of heat switches 112 are configured to thermally connect the HMHC blocks 108 to the device 102 (e.g., via the thermally conductive material 110) and to thermally disconnect the HMHC blocks 108 from the device 102. The second set of heat switches 114 are configured to thermally connect the HMHC blocks 108 to the second cooling circuit 106 and to thermally disconnect the HMHC blocks 108 from the second cooling circuit 106. In some implementations, the first set of heat switches 112 and the second set of heat switches 114 may be sorption-pumping-based gas-gap heat switches. In this case, a heat switch 112 or 114 includes a sorption pump, such as a block of charcoal, that adsorbs an exchange gas (e.g., helium) when cooled and releases the exchange gas when heated. When the sorption pump is heated (e.g., by a voltage applied to heat switch), the released exchange gas lies in a gap between the components connected by the heat switch (e.g., an HMHC block 108 and the thermally conductive material 110, or an HMHC block 108 and the second cooling circuit 106) resulting in high thermal conductivity between the components connected by the heat switch. When the sorption pump is cooled (e.g., by stopping the voltage from being applied to the heat switch), the exchange gas is adsorbed and the gap between the components acts as an insulator, resulting in low thermal conductivity between the components.

As shown in FIG. 1A, the first set of heat switches 112 includes heat switches 112a, 112b, 112c, and 112d connected to the first HMHC block 108a, the second HMHC block 108b, the third HMHC block 108c, and the fourth HMHC block 108d, respectively. Each heat switch 112 is configured to selectively thermally connect a respective HMHC block 108 to the device 102 via the thermally conductive material 110 to boost or otherwise manipulate the cooling of the device 102, and to selectively thermally disconnect the respective HMHC block 108 from the device 102. For example, each heat switch 112 is configured to toggle between thermally connecting the respective HMHC block 108 to the device 102 (via the thermally conductive material 110) when actuated by a voltage applied to the heat switch 112, and thermally disconnecting the respective HMHC block 108 from the device 102 when not actuated (e.g., when the voltage is not applied to the heat switch 112). In the implementation shown in FIG. 1A, when the heat switches 112 thermally connect one or more of the HMHC blocks 108 to the device 102 via the thermally conductive material, the thermally conductive material 110 distributes the cooling from the one or more HMHC blocks 108 (e.g., the heat transfer due to the one or more HMHC blocks 108) over the second surface of the device 102.

The second set of heat switches 114 includes heat switches 114a, 114b, 114c, and 114d connected to the first HMHC block 108a, the second HMHC block 108b, the third HMHC block 108c, and the fourth HMHC block 108d, respectively. Each heat switch 114 is configured to selectively thermally connect a respective HMHC block 108 to the second cooling circuit 106 to cool the respective HMHC block 108, and to selectively thermally disconnect the respective HMHC block 108 from the second cooling circuit 106. For example, each heat switch 114 is configured to toggle between thermally connecting the respective HMHC block 108 to the second cooling circuit 106 when actuated by a voltage applied to the heat switch 114 and thermally disconnecting the respective HMHC block 108 from the second cooling circuit 106 when not actuated (e.g., when the voltage is not applied to the heat switch 114). The second cooling circuit 106 is configured to perform cooling (e.g., cryogenic cooling) of the HMHC blocks 108 when the HMHC blocks 108 are thermally connected to the second cooling circuit 106 by the heat switches 114. For example, the second cooling circuit 106 may perform cooling of one or more HMHC blocks 108 that are thermally connected to the second cooling circuit 106 using direct immersion in liquid cryogens, a liquid cryogen heat exchanger, one or more helium pulse tubes, or a combination thereof.

The controller 116 is configured to control the first set of heat switches 112 to thermally connect or disconnect the HMHC blocks 108 to or from the device 102 (e.g., via the thermally conductive material 110). The controller 116 controls each heat switch 112 individually to selectively thermally connect a respective HMHC block 108 to the device 102 or thermally disconnect the respective HMHC block 108 from the device 102. For example, the controller 116 may cause a voltage (e.g., from a voltage source) to be applied to a heat switch 112 to actuate or switch on the heat switch 112 in order to control the heat switch 112 to thermally connect the respective HMHC block 108 to the device 102. The controller 116 may cause the voltage to stop being applied to the heat switch 112 to de-actuate or switch off the heat switch 112 in order to control the heat switch 112 to thermally disconnect the respective HMHC block 108 from the device 102.

The controller 116 is configured to control the second set of heat switches 114 to thermally connect or disconnect the HMHC blocks 108 to or from the second cooling circuit 106. The controller 116 controls each heat switch 114 individually to selectively thermally connect a respective HMHC block 108 to the second cooling circuit 106 or thermally disconnect the respective HMHC block 108 from the second cooling circuit 106. For example, the controller 116 may cause a voltage (e.g., from a voltage source) to be applied to a heat switch 114 to actuate or switch on the heat switch 114 in order to control the heat switch 114 to thermally connect the respective HMHC block 108 to the second cooling circuit 106. The controller 116 may cause the voltage to stop being applied to the heat switch 114 to de-actuate or switch off the heat switch 114 in order to control the heat switch 114 to thermally disconnect the respective HMHC block 108 from the second cooling circuit 106.

The controller 116 may control the first set of heat switches 112 and the second set of heat switches 114 such that one or more HMHC blocks 108 are in an active state. An HMHC block 108 in the active state is thermally connected to the device 102 (e.g., via the thermally conductive material 110). Accordingly, an HMHC block 108 in the active state is actively cooling the device 102 (e.g., boosting or otherwise manipulating the cooling of the device 102 that is being performed by the first cooling circuit 104). In some implementations, an HMHC block 108 in the active state is thermally connected to the device 102 and thermally disconnected from the second cooling circuit 106. In some other implementations, an HMHC block 108 in the active state may remain thermally connected to the second cooling circuit 106 while also being thermally connected to the device 102. Additionally, or alternatively, the controller 116 may control the first set of heat switches 112 and the second set of heat switches 114 such that one or more HMHC blocks 108 are in an inactive state. An HMHC block 108 in the inactive state is thermally disconnected from the device 102 and thermally connected to the second cooling circuit 106. Accordingly, an HMHC block 108 in the inactive state is not actively cooling the device 102, and is being cooled by the second cooling circuit 106.

In some implementations, the controller 116 may control the first set of heat switches 112 and the second set of heat switches 114 such that one or more HMHC blocks 108 are in the active state while the remaining HMHC blocks 108 are in the inactive state. The controller 116 may further control the first set of heat switches 112 and the second set of heat switches 114 to cycle or rotate which of the one or more HMHC blocks 108 are in the active state and which of the one or more HMHC blocks 108 are in the inactive state. For example, as shown in FIG. 1A, the first HMHC block 108a is in the active state, and the second HMHC block 108b, the third HMHC block 108c, and the fourth HMHC block 108d are in the inactive state. In this example, once the temperatures of the first HMHC block 108a and the device 102 have equilibrated (e.g., within a threshold), the controller 116 may control the heat switches 112a and 114a to switch the first HMHC block 108a to the inactive state (e.g., by thermally disconnecting the first HMHC block 108a from the device 102 and thermally connecting the first HMHC block 108a to the second cooling circuit 106) and control the heat switches 112b and 114b to switch the second HMHC block 108b to the active state (e.g., by thermally connecting the second HMHC block 108b to the device 102 and thermally disconnecting the second HMHC block 108b from the second cooling circuit 106).

The controller may repeat this process to cycle through each of the HMHC blocks 108 in the active state, while the other HMHC blocks 108 are being cooled by the second cooling circuit 106 while in the inactive state. In some other examples, the controller 116 may control the heat switches 112 and 114 so that multiple HMHC blocks 108 are in the active state at a given time.

The controller 116 includes one or more devices capable of controlling the first set of heat switches 112 and the second set of heat switches 114 as described herein. In some implementations, the controller 116 may be a computing device or a similar type of device. The controller 116 may include one or more memories and one or more processors communicatively coupled to the one or more memories. A processor may include a central processing unit, a graphics processing unit, a microprocessor, a controller, a microcontroller, a digital signal processor, a field-programmable gate array, an application-specific integrated circuit, and/or another type of processing component. The processor may be implemented in hardware, firmware, or a combination of hardware and software. The processor may be capable of being programmed to perform one or more operations or processes described herein. A memory may include volatile and/or nonvolatile memory. For example, the memory may include random access memory (RAM), read only memory (ROM), a hard disk drive, and/or another type of memory (e.g., a flash memory, a magnetic memory, and/or an optical memory). The memory may be a non-transitory computer-readable medium. The memory may store information, one or more instructions, and/or software (e.g., one or more software applications) related to the operation of the controller 116.

Although FIG. 1A only shows two cooling circuits (e.g., the first cooling circuit 104 and the second cooling circuit 106), in some other implementations, the cryogenic cooling system may include more than two (e.g., three, four, etc.) cooling circuits. In some implementations, the cryogenic cooling system may include one or more additional cooling circuits (e.g., a third cooling circuit, a fourth cooling circuit, etc.) for directly cooling the device 102, similar to the first cooling circuit 104 described herein. For example, the first cooling circuit 104 and the one or more additional cooling circuits may each be thermally connected to the device 102 (e.g., at different surfaces, sides, or regions of the device 102) to perform cooling of the device 102. Additionally, or alternatively, in some implementations, the cryogenic cooling system may include one or more additional cooling circuits (e.g., a third cooling circuit, a fourth cooling circuit, etc.) for cooling HMHC blocks 108, similar to the second cooling circuit 106 described herein. For example, the second cooling circuit 106 and the one or more additional cooling circuits may each be used to cool a respective set of HMHC blocks 108, which may be used to boost (or otherwise manipulate) cooling of the device 102.

FIG. 1B shows an example process for multiple cryogenic heat sink rotation using the cryogenic cooling system shown in FIG. 1A. As shown in FIG. 1B, and by reference number 120, the cryogenic cooling system is cooled to a base temperature. In some implementations, the cryogenic cooling system is cooled to the base temperature by activating the first cooling circuit 104 to begin cooling of the device 102, activating the second cooling circuit 106, controlling the second set of heat switches 114 to thermally connect all of the HMHC blocks 108 to the second cooling circuit 106, and controlling the first set of heat switches 112 to thermally connect all of the HMHC blocks 108 to the device 102. That is, during an initial cooling phase, the controller 116 may control the heat switches 112a, 112b, 112c, and 112d to thermally connect the first HMHC block 108a, the second HMHC block 108b, the third HMHC block 108c, and the fourth HMHC block 108d, respectively, to the device 102, and the controller 116 may control the heat switches 114a, 114b, 114c, and 114d to thermally connect the first HMHC block 108a, the second HMHC block 108b, the third HMHC block 108c, and the fourth HMHC block 108d, respectively, to the second cooling circuit 106. In this way, the cooling performed by the first cooling circuit 104 is boosted by the HMHC blocks 108 and the second cooling circuit 106, resulting in faster cooling to the base temperature.

As shown by reference number 125, the HMHC blocks 108 are thermally disconnected from the device 102. Once the cryogenic cooling system is cooled to the base temperature, the controller controls the heat switches 112 (e.g., 112a, 112b, 112c, and 112d) to thermally disconnect the HMHC blocks 108 (e.g., the first HMHC block 108a, the second HMHC block 108b, the third HMHC block 108c, and the fourth HMHC block 108d) from the device 102. At this time, the HMHC blocks 108 remain thermally connected to the second cooling circuit 106, such that the second cooling circuit 106 is cooling the HMHC blocks 108. That is, the controller continues controlling the heat switches 114 (e.g., 114a, 114b, 114c, and 114d) to thermally connect the HMHC blocks 108 (e.g., the first HMHC block 108a, the second HMHC block 108b, the third HMHC block 108c, and the fourth HMHC block 108d) to the second cooling circuit 106.

As shown by reference number 130, the device 102 begins high thermal load activities. The first cooling circuit 104 performs persistent cooling of the device 102 operates. However, the cooling performed by the first cooling circuit 104 may not be sufficient to maintain the base temperature due to an additional heat load resulting from the high thermal load activities.

As shown by reference number 135, the first HMHC block 108 a (labeled “HMHC1” in FIG. 1B) is thermally connected to the device 102 and thermally disconnected from the second cooling circuit 106 (labeled “CC2” in FIG. 1B). The controller 116 controls the heat switch 112a to thermally connect the first HMHC block 108a to the device 102 and controls the heat switch 114a to thermally disconnect the first HMHC block 108a from the second cooling circuit 106. That is, the controller 116 controls the heat switches 112a and 114a to switch the first HMHC block 108a to the active state to manipulate the cooling of the device 102 (e.g., to boost the cooling of the device 102 being performed by the first cooling circuit 104). The controller 116 controls the heat switches 112a and 114a to thermally connect the first HMHC block 108a to the device 102 and thermally disconnect the first HMHC block 108a from the second cooling circuit 106 at a first time. For example, the first HMHC block 108a may be thermally connected to the device 102 and thermally disconnected from the second cooling circuit 106 simultaneously or nearly simultaneously.

The second HMHC block 108b, the third HMHC block 108c, and the fourth HMHC block 108d remain in the inactive state (e.g., thermally disconnected from the device 102 and thermally connected to the second cooling circuit 106) when the first HMHC block 108a is in the active state. Switching the first HMHC block 108a to the active state (e.g., thermally connecting the first HMHC block 108a to the device 102) begins an HMHC block cycle, shown by reference numbers 140 through 175 in FIG. 1B, which cycles through each of the HMHC blocks 108 being switched to the active state in order to manipulate/boost cooling of the device 102, while the other HMHC blocks 108 are in the inactive state. The first cooling circuit 104 and the second cooling circuit 106 are in continuous operation during the HMHC cycle to provide cooling of the device 102 and cooling of the HMHC blocks 108 in the inactive state, respectively.

As shown by reference number 140, the first HMHC block 108a remains thermally connected to the device 102 and thermally disconnected from the second cooling circuit 106 until the first HMHC block 108a and the device 102 nearly equilibrate. That is, the controller controls the heat switches 112a and 114a to keep the first HMHC block 108a in the active state to boost/manipulate the cooling of the device 102 until the temperatures of the first HMHC block 108a and the device 102 nearly equilibrate. In some implementations, the first HMHC block 108a may remain in the active state (e.g., thermally connected to the device 102 and thermally disconnected from the second cooling circuit 106) for a predetermined amount of time that corresponds to equilibration (or near equilibration) of the temperatures of the first HMHC block 108a and the device 102. In some implementations, the first HMHC block 108a may remain in the active state (e.g., thermally connected to the device 102 and thermally disconnected from the second cooling circuit 106) until the temperature of the first HMHC block 108a equilibrates to within a threshold of the temperature of the device 102.

As shown by reference number 145, the first HMHC block 108 a is thermally disconnected from the device 102, the second HMHC block 108b (labeled “HMHC2” in FIG. 1B) is thermally connected to the device 102, the second HMHC block 108b is thermally disconnected from the second cooling circuit 106, and the first HMHC block 108a is thermally reconnected to the second cooling circuit 106. At a second time (e.g., once the temperatures of the first HMHC block 108a and the device 102 nearly equilibrate), the controller 116 controls the heat switch 112a to thermally disconnect the first HMHC block 108a from the device 102, controls the heat switch 114a to thermally reconnect the first HMHC block 108a to the second cooling circuit 106, controls the heat switch 112b to thermally connect the second HMHC block 108b to the device 102, and controls the heat switch 114b to thermally disconnect the second HMHC block 108b from the second cooling circuit 106. That is, the controller 116 controls the heat switches 112a and 114a to switch the first HMHC block 108a from the active state back to the inactive state to be cooled by the second cooling circuit 106, and the controller 116 controls the heat switches 112b and 114b to switch the second HMHC block 108b to the active state to manipulate the cooling of the device 102 (e.g., to boost the cooling of the device 102 being performed by the first cooling circuit 104). In some examples, the controller 116 may control the heat switches 112a, 114a, 112b, and 114b to thermally disconnect the first HMHC block 108a from the device 102, thermally reconnect the first HMHC block 108a to the second cooling circuit 106, thermally connect the second HMHC block 108b to the device 102, and/or thermally disconnect the second HMHC block 108b from the second cooling circuit 106 simultaneously or nearly simultaneously.

As shown by reference number 150, the second HMHC block 108b remains thermally connected to the device 102 and thermally disconnected from the second cooling circuit 106 until the second HMHC block 108b and the device 102 nearly equilibrate. That is, the controller controls the heat switches 112b and 114b to keep the second HMHC block 108b in the active state to boost/manipulate the cooling of the device 102 until the temperatures of the second HMHC block 108b and the device 102 nearly equilibrate. In some implementations, the second HMHC block 108b may remain in the active state (e.g., thermally connected to the device 102 and thermally disconnected from the second cooling circuit 106) for a predetermined amount of time that corresponds to equilibration (or near equilibration) of the temperatures of the second HMHC block 108b and the device 102. In some implementations, the second HMHC block 108b may remain in the active state (e.g., thermally connected to the device 102 and thermally disconnected from the second cooling circuit 106) until the temperature of the second HMHC block 108b equilibrates to within a threshold of the temperature of the device 102.

As shown by reference number 155, the second HMHC block 108 b is thermally disconnected from the device 102, the third HMHC block 108c (labeled “HMHC3” in FIG. 1B) is thermally connected to the device 102, the third HMHC block 108c is thermally disconnected from the second cooling circuit 106, and the second HMHC block 108b is thermally reconnected to the second cooling circuit 106. At a third time (e.g., once the temperatures of the second HMHC block 108b and the device 102 nearly equilibrate), the controller 116 controls the heat switch 112b to thermally disconnect the second HMHC block 108b from the device 102, controls the heat switch 114b to thermally reconnect the second HMHC block 108b to the second cooling circuit 106, controls the heat switch 112c to thermally connect the third HMHC block 108c to the device 102, and controls the heat switch 114c to thermally disconnect the third HMHC block 108c from the second cooling circuit 106. That is, the controller 116 controls the heat switches 112b and 114b to switch the second HMHC block 108b from the active state back to the inactive state to be cooled by the second cooling circuit 106, and the controller 116 controls the heat switches 112c and 114c to switch the third HMHC block 108c to the active state to manipulate the cooling of the device 102 (e.g., to boost the cooling of the device 102 being performed by the first cooling circuit 104). In some examples, the controller 116 may control the heat switches 112b, 114b, 112c, and 114c to thermally disconnect the second HMHC block 108b from the device 102, thermally reconnect the second HMHC block 108b to the second cooling circuit 106, thermally connect the third HMHC block 108c to the device 102, and/or thermally disconnect the third HMHC block 108c from the second cooling circuit 106 simultaneously or nearly simultaneously.

As shown by reference number 160, the third HMHC block 108 c remains thermally connected to the device 102 and thermally disconnected from the second cooling circuit 106 until the third HMHC block 108c and the device 102 nearly equilibrate. That is, the controller controls the heat switches 112c and 114c to keep the third HMHC block 108c in the active state to boost/manipulate the cooling of the device 102 until the temperatures of the third HMHC block 108c and the device 102 nearly equilibrate. In some implementations, the third HMHC block 108c may remain in the active state (e.g., thermally connected to the device 102 and thermally disconnected from the second cooling circuit 106) for a predetermined amount of time that corresponds to equilibration (or near equilibration) of the temperatures of the third HMHC block 108c and the device 102. In some implementations, the third HMHC block 108c may remain in the active state (e.g., thermally connected to the device 102 and thermally disconnected from the second cooling circuit 106) until the temperature of the third HMHC block 108c equilibrates to within a threshold of the temperature of the device 102.

As shown by reference number 165, the third HMHC block 108 c is thermally disconnected from the device 102, the fourth HMHC block 108d (labeled “HMHC4” in FIG. 1B) is thermally connected to the device 102, the fourth HMHC block 108d is thermally disconnected from the second cooling circuit 106, and the third HMHC block 108c is thermally reconnected to the second cooling circuit 106. At a fourth time (e.g., once the temperatures of the third HMHC block 108c and the device 102 nearly equilibrate), the controller 116 controls the heat switch 112c to thermally disconnect the third HMHC block 108c from the device 102, controls the heat switch 114c to thermally reconnect the third HMHC block 108c to the second cooling circuit 106, controls the heat switch 112d to thermally connect the fourth HMHC block 108d to the device 102, and controls the heat switch 114d to thermally disconnect the fourth HMHC block 108d from the second cooling circuit 106. That is, the controller 116 controls the heat switches 112c and 114c to switch the third HMHC block 108c from the active state back to the inactive state to be cooled by the second cooling circuit 106, and the controller 116 controls the heat switches 112d and 114d to switch the fourth HMHC block 108d to the active state to manipulate the cooling of the device 102 (e.g., to boost the cooling of the device 102 being performed by the first cooling circuit 104). In some examples, the controller 116 may control the heat switches 112c, 114c, 112d, and 114d to thermally disconnect the third HMHC block 108c from the device 102, thermally reconnect the third HMHC block 108c to the second cooling circuit 106, thermally connect the fourth HMHC block 108d to the device 102, and/or thermally disconnect the fourth HMHC block 108d from the second cooling circuit 106 simultaneously or nearly simultaneously.

As shown by reference number 170, the fourth HMHC block 108 d remains thermally connected to the device 102 and thermally disconnected from the second cooling circuit 106 until the fourth HMHC block 108d and the device 102 nearly equilibrate. That is, the controller controls the heat switches 112d and 114d to keep the fourth HMHC block 108d in the active state to boost/manipulate the cooling of the device 102 until the temperatures of the fourth HMHC block 108d and the device 102 nearly equilibrate. In some implementations, the fourth HMHC block 108d may remain in the active state (e.g., thermally connected to the device 102 and thermally disconnected from the second cooling circuit 106) for a predetermined amount of time that corresponds to equilibration (or near equilibration) of the temperatures of the fourth HMHC block 108d and the device 102. In some implementations, the fourth HMHC block 108d may remain in the active state (e.g., thermally connected to the device 102 and thermally disconnected from the second cooling circuit 106) until the temperature of the fourth HMHC block 108d equilibrates to within a threshold of the temperature of the device 102.

As shown by reference number 175, the fourth HMHC block 108 d is thermally disconnected from the device 102, the first HMHC block 108a is thermally connected to the device 102, the first HMHC block 108a is thermally disconnected from the second cooling circuit 106, and the fourth HMHC block 108d is thermally reconnected to the second cooling circuit 106. At a fifth time (e.g., once the temperatures of the fourth HMHC block 108d and the device 102 nearly equilibrate), the controller 116 controls the heat switch 112d to thermally disconnect the fourth HMHC block 108d from the device 102, controls the heat switch 114d to thermally reconnect the fourth HMHC block 108d to the second cooling circuit 106, controls the heat switch 112a to thermally connect the first HMHC block 108a to the device 102, and controls the heat switch 114a to thermally disconnect the first HMHC block 108a from the second cooling circuit 106. That is, the controller 116 controls the heat switches 112d and 114d to switch the third HMHC block 108c from the active state back to the inactive state to be cooled by the second cooling circuit 106, and the controller 116 controls the heat switches 112a and 114a to switch the first HMHC block 108a, which has been cooled by the second cooling circuit 106 while in the inactive state, back to the active state to manipulate the cooling of the device 102 (e.g., to boost the cooling of the device 102 being performed by the first cooling circuit 104). In some examples, the controller 116 may control the heat switches 112d, 114d, 112a, and 114a to thermally disconnect the fourth HMHC block 108d from the device 102, thermally reconnect the fourth HMHC block 108d to the second cooling circuit 106, thermally connect the first HMHC block 108a to the device 102, and/or thermally disconnect the first HMHC block 108a from the second cooling circuit 106 simultaneously or nearly simultaneously.

As shown by reference number 180, the HMHC block cycle (e.g., as described in connection with reference numbers 140 through 175) is repeated until the device 102 completes the high thermal load activities. The controller 116 controls the first set of heat switches 112 and the second set of heat switches 114 to cycle which HMHC block 108 is in the active state (e.g., thermally connected to the device 102 and thermally disconnected from the second cooling circuit 106) to boost/manipulate the cooling of the device 102, while the other HMHC blocks 108 are in the inactive state being cooled by the second cooling circuit 106. In this way, each time the temperature of HMHC block 108 being used to boost/manipulate the cooling of the device 102 equilibrates (or nearly equilibrates) with the temperature of device 102, a different HMHC block 108 that has been cooled by the second cooling circuit 106 is cycled into the active state to boost/manipulate cooling of the device.

Although the process described in connection with FIG. 1B cycles through the HMHC blocks 108 in the active state one at a time, in some other implementations, multiple HMHC blocks 108 may be thermally connected to the device 102 at the same time. In such implementations, the controller may control the heat switches 112 and 114 to cycle through different combinations of multiple HMHC blocks 108 that are in the active state (e.g., thermally connected to the device 102) to boost/manipulate cooling of the device 102, while the remaining HMHC blocks 108 are in the inactive state.

As indicated above, FIGS. 1A-1B are provided as an example. Other examples may differ from what is described with regard to FIGS. 1A-1B. The number and arrangement of devices or components shown in FIGS. 1A-1B are provided as an example. In practice, there may be additional devices or components, fewer devices or components, different devices or components, or differently arranged devices or components than those shown in FIGS. 1A-1B.

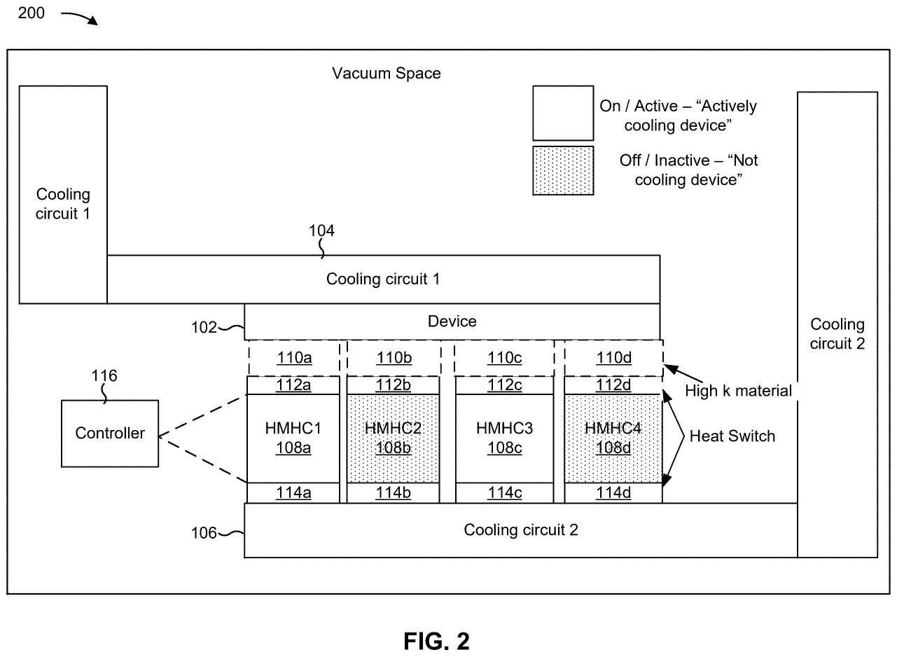

FIG. 2 is a diagram of an example implementation 200 associated with multiple cryogenic heat sink rotation. As shown in FIG. 2, example implementation 200 includes a cryogenic cooling system and a device 102. The device 102 is similar to the device described above in connection with FIGS. 1A-1B. The cryogenic cooling system and the components of the cryogenic cooling system are similar to the systems described above in connection with FIGS. 1A-1B, other than differences described in connection with FIG. 2.

As shown in FIG. 2, in example implementation 200, the cryogenic cooling system includes a plurality of thermally conductive material segments 110a-110d (e.g., instead of the thermally conductive material 110 shown in FIG. 1). The thermally conductive material segments 110a-110d are separate segments of a material with a high thermal conductivity (k), such as copper or gold, among other examples. The thermally conductive material segments 110a-110d are connected to different regions of the device 102, and enable the cryogenic cooling system to generate a thermal gradient across the different regions of the device. As shown in FIG. 2, in example implementation 200, the first cooling circuit 104 is connected to a first surface of the device 102, and the thermally conductive material segments 110a-110d are connected to different regions on a second surface (e.g., opposite the first surface) of the device 102.

Each of the thermally conductive material segments 110a-110d connects a respective heat switch 112a-112d of the first set of heat switches 112 and a region of the device 102. For example, the thermally conductive material segment 110a connects the heat switch 112a to a first region of the device 102, the thermally conductive material segment 110b connects the heat switch 112b to a second region of the device 102, the thermally conductive material segment 110c connects the heat switch 112c to a third region of the device 102, and the thermally conductive material segment 110d connects the heat switch 112d to a fourth region of the device 102. When a heat switch 112 is controlled (e.g., by the controller 116) to thermally connect an HMHC block 108 to the device 102, the heat switch 112 thermally connects the HMHC block 108 to the device 102 via a respective thermally conductive material segment (e.g., 110a, 110b, 110c, or 110d) and the HMHC block 108 boosts or otherwise manipulates cooling at the region of the device 102 connected to thermally conductive material segment. For example, as shown in FIG. 2, the first HMHC block 108a and the third HMHC block 108c are in the active state. In this example, the first HMHC block 108a is thermally connected to the first region of the device 102 via the thermally conductive material segment 110a, and the third HMHC block 108c is thermally connected to the third region of the device 102 via the thermally conductive material segment 110c.

In some implementations, by thermally connecting the cooling HMHC blocks 108 on localized regions or sections of the device 102, as shown in FIG. 2, the cryogenic cooling system can control local cooling and generate a thermal gradient across the different regions of the device 102. The controller 116 may control the thermal gradient across the regions of the device 102 by controlling the heat switches 112 and 114 to toggle the one or more of the HMHC blocks 108 between the active state and the inactive state to control local cooling in the different regions of the device 102 and generate the thermal gradient between the first cooling circuit 104 and the different regions of the device 102. The generation of the thermal gradients across the regions of the device 102 may enable the cryogenic cooling system to achieve novel physics phenomena, such as thermoelectric effects, and/or optimized temperatures across the different regions of the device 102. In some examples, generating the thermal gradient may be beneficial in devices that leverage the Seebeck effect or other thermoelectric effects at cryogenic temperatures. Additionally, or alternatively, for chips with arrays of superconducting devices, generating localized thermal gradients may enable modulation of the critical current via the localized thermal gradients.

As indicated above, FIG. 2 is provided as an example. Other examples may differ from what is described with regard to FIG. 2. The number and arrangement of devices or components shown in FIG. 2 are provided as an example. In practice, there may be additional devices or components, fewer devices or components, different devices or components, or differently arranged devices or components than those shown in FIG. 2.

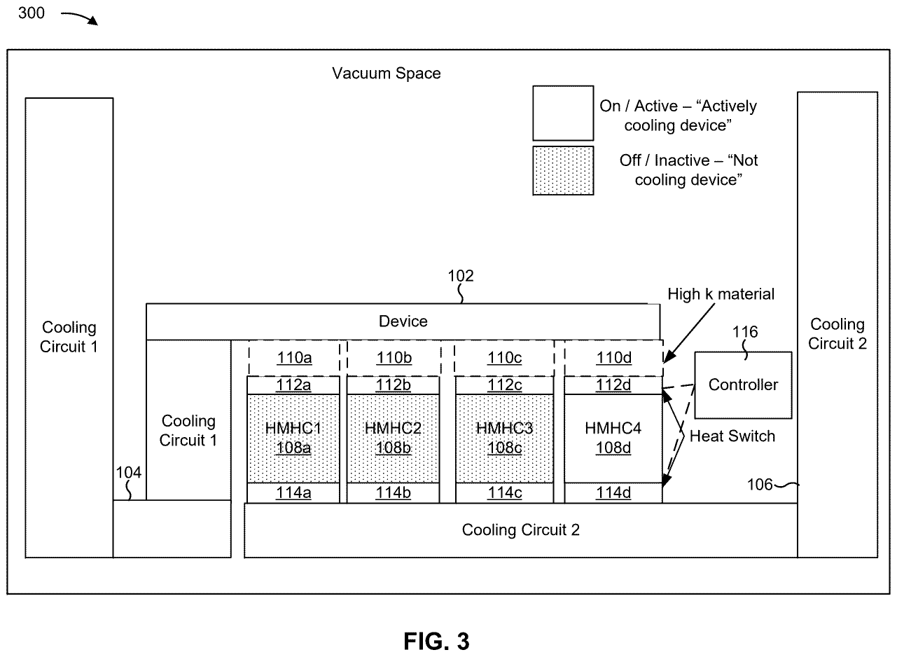

FIG. 3 is a diagram of an example implementation 300 associated with multiple cryogenic heat sink rotation. As shown in FIG. 3, example implementation 300 includes a cryogenic cooling system and a device 102. The device 102 is similar to the devices described above in connection with FIGS. 1A-1B and FIG. 2. The cryogenic cooling system and the components of the cryogenic cooling system are similar to the systems described above in connection with FIGS. 1A-1B and FIG. 2, other than differences described in connection with FIG. 3.

As shown in FIG. 3, in example implementation 300, the cryogenic cooling system includes a plurality of thermally conductive material segments 110a-110d connected to different regions of the device 102, which enable the cryogenic cooling system to generate a thermal gradient across the different regions of the device 102, similar to the system described above in connection with FIG. 2. As shown in FIG. 3, in example implementation 300, the first cooling circuit 104 and the thermally conductive material segments 110a-110d are connected to the device 102 at respective regions along a first surface of the device 102. By connecting the first cooling circuit 104 and the thermally conductive material segments 110a-110d to different regions along a same surface of the device 102, the cryogenic cooling system shown in example implementation 300 of FIG. 3 has a different heat flow path from the cryogenic cooling system shown in example implementation 200 of FIG. 2. Accordingly, the cryogenic cooling system of FIG. 3 may be capable of generating different thermal gradients from those of the cryogenic cooling system of FIG. 2. For example, the cryogenic cooling system of FIG. 3 may be capable of generating stronger thermal gradients between the first cooling circuit 104 and the one or more HMHC blocks 108 in the active state, as compared to the cryogenic cooling system of FIG. 2.

In some implementations, the controller 116 may control the thermal gradient across the regions of the device 102 by controlling the heat switches 112 and 114 to toggle the one or more of the HMHC blocks 108 between the active state and the inactive state to control local cooling in the different regions of the device 102 and generate the thermal gradient between the first cooling circuit 104 and the different regions of the device 102. For example, as shown in FIG. 3, the fourth HMHC block 108d is in the active state, and the first HMHC block 108a, the second HMHC block 108b, and the third HMHC block 108c are in the inactive state. In this example, the fourth HMHC block 108d is thermally connected to a corresponding region of the device 102 via the thermally conductive material segment 110d, which may result in a thermal gradient between a region of the device 102 at which the first cooling circuit 104 is connected and the region of the device at which the fourth HMHC block 108d is thermally connected via the thermally conductive material segment 110d. The generation of the thermal gradients across the regions of the device 102 may enable the cryogenic cooling system to achieve novel physics phenomena and/or optimized temperatures across the different regions of the device 102. In some examples, generating the thermal gradient may be beneficial in devices that leverage the Seebeck effect or other thermoelectric effects at cryogenic temperatures. Additionally, or alternatively, for chips with arrays of superconducting devices, generating localized thermal gradients may enable modulation of the critical current via the localized thermal gradients.

As indicated above, FIG. 3 is provided as an example. Other examples may differ from what is described with regard to FIG. 3. The number and arrangement of devices or components shown in FIG. 3 are provided as an example. In practice, there may be additional devices or components, fewer devices or components, different devices or components, or differently arranged devices or components than those shown in FIG. 3.

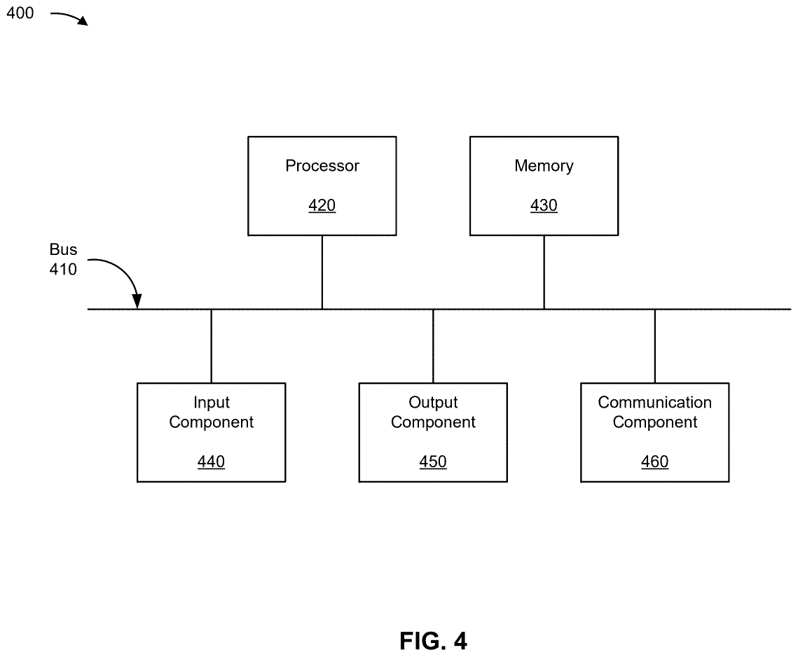

FIG. 4 is a diagram of example components of a device 400 associated with multiple cryogenic heat sink rotation. The device 400 corresponds to one or more of the controller 116 or the device 102. In some implementations, the controller 116 and/or the device 102 include one or more devices 400 and/or one or more components of the device 400. In the example shown in FIG. 4, the device 400 includes a bus 410, a processor 420, a memory 430, an input component 440, an output component 450, and/or a communication component 460.

The bus 410 includes one or more components that enable wired and/or wireless communication among the components of the device 400. The bus 410 couples together two or more components of FIG. 4, such as via operative coupling, communicative coupling, electronic coupling, and/or electric coupling. For example, the bus 410 may include an electrical connection (e.g., a wire, a trace, and/or a lead) and/or a wireless bus. The processor 420 includes a central processing unit, a graphics processing unit, a microprocessor, a controller, a microcontroller, a digital signal processor, a field-programmable gate array, an application-specific integrated circuit, and/or another type of processing component. The processor 420 may be implemented in hardware, firmware, or a combination of hardware and software. In some implementations, the processor 420 includes one or more processors capable of being programmed to perform one or more operations or processes described elsewhere herein.

The memory 430 includes volatile and/or nonvolatile memory, such as RAM, ROM, a hard disk drive, and/or another type of memory (e.g., a flash memory, a magnetic memory, and/or an optical memory). The memory 430 may include internal memory (e.g., RAM, ROM, or a hard disk drive) and/or removable memory (e.g., removable via a universal serial bus connection). In some implementations, the memory 430 is a non-transitory computer-readable medium. The memory 430 stores information, one or more instructions, and/or software (e.g., one or more software applications) related to the operation of the device 400. In some implementations, the memory 430 includes one or more memories that are coupled (e.g., communicatively coupled) to one or more processors (e.g., processor 420), such as via the bus 410. Communicative coupling between a processor 420 and a memory 430 enables the processor 420 to read and/or process information stored in the memory 430 and/or to store information in the memory 430.

The input component 440 enables the device 400 to receive input, such as user input and/or sensed input. For example, the input component 440 may include a touch screen, a keyboard, a keypad, a mouse, a button, a microphone, a switch, a sensor, a global positioning system sensor, a global navigation satellite system sensor, an accelerometer, a gyroscope, and/or an actuator. The output component 450 enables the device 400 to provide output, such as via a display, a speaker, and/or a light-emitting diode. The communication component 460 enables the device 400 to communicate with other devices via a wired connection and/or a wireless connection. For example, the communication component 460 may include a receiver, a transmitter, a transceiver, a modem, a network interface card, and/or an antenna.

In some implementations, the device 400 performs one or more operations or processes described herein. For example, a non-transitory computer-readable medium (e.g., memory 430) may store a set of instructions (e.g., one or more instructions or code) for execution by the processor 420. The processor 420 may execute the set of instructions to perform one or more operations or processes described herein. In some implementations, execution of the set of instructions, by one or more processors 420, causes the one or more processors 420 and/or the device 400 to perform one or more operations or processes described herein. In some implementations, hardwired circuitry is used instead of or in combination with the instructions to perform one or more operations or processes described herein. Additionally, or alternatively, the processor 420 may be configured to perform one or more operations or processes described herein. Thus, implementations described herein are not limited to any specific combination of hardware circuitry and software.

The number and arrangement of components shown in FIG. 4 are provided as an example. The device 400 may include additional components, fewer components, different components, or differently arranged components than those shown in FIG. 4. Additionally, or alternatively, a set of components (e.g., one or more components) of the device 400 may perform one or more functions described as being performed by another set of components of the device 400.

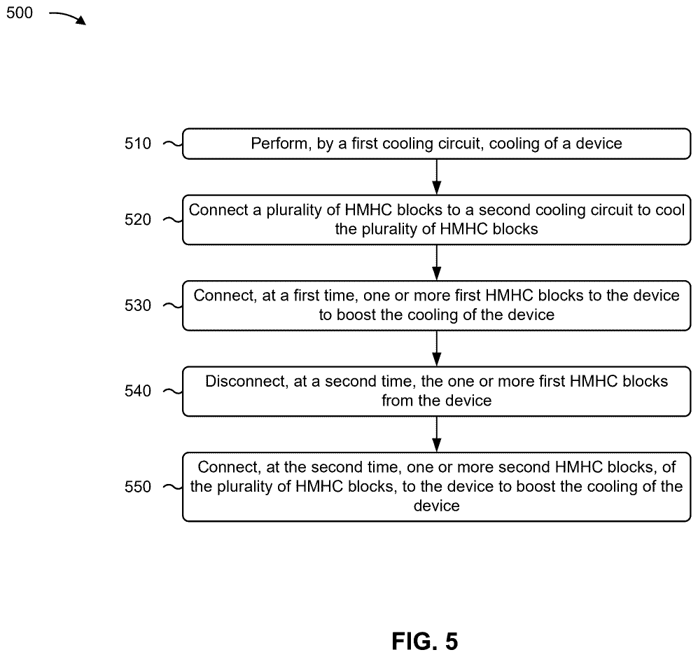

FIG. 5 is a flowchart of an example process 500 associated with multiple cryogenic heat sink rotation. One or more process blocks of FIG. 5 are performed by a cryogenic cooling system and/or by one or more components of the cryogenic cooling system, such as a controller (e.g., controller 116), a first cooling circuit (e.g., first cooling circuit 104), a second cooling circuit (e.g., second cooling circuit 106), one or more HMHC blocks (e.g., HMHC blocks 108), a first set of heat switches (e.g., heat switches 112), a second set of heat switches (e.g., heat switches 114), a thermally conductive material (e.g., thermally conductive material 110), and/or one or more thermally conductive material segments (e.g., thermally conductive material segments 110a-110d). Additionally, or alternatively, one or more process blocks of FIG. 5 may be performed by one or more components of device 400, such as processor 420, memory 430, input component 440, output component 450, and/or communication component 460.

As shown in FIG. 5, process 500 includes performing cooling of a device (block 510). For example, the first cooling circuit may perform cooling of a device, as described above.

As further shown in FIG. 5, process 500 includes connecting a plurality of HMHC blocks to a second cooling circuit to cool the plurality of HMHC blocks (block 520). For example, the controller and/or the second set of heat switches may connect a plurality of HMHC blocks to a second cooling circuit to cool the plurality of HMHC blocks, as described above.

As further shown in FIG. 5, process 500 includes connecting, at a first time, one or more first HMHC blocks to the device to manipulate the cooling of the device (block 530). For example, the controller and/or the first set of heat switches may connect, at a first time, one or more first HMHC blocks to the device to manipulate the cooling of the device, as described above.

As further shown in FIG. 5, process 500 includes disconnecting, at a second time, the one or more first HMHC blocks from the device (block 540). For example, the controller and/or the first set of heat switches may disconnect, at a second time, the one or more first HMHC blocks from the device, as described above.

As further shown in FIG. 5, process 500 includes connecting, at the second time, one or more second HMHC blocks, of the plurality of HMHC blocks, to the device to manipulate the cooling of the device (block 550). For example, the controller and/or the first set of heat switches may connect, at the second time, one or more second HMHC blocks, of the plurality of HMHC blocks, to the device to manipulate the cooling of the device, as described above.

Process 500 may include additional aspects, such as any single aspect or any combination of aspects described below and/or in connection with one or more other processes described elsewhere herein.

In a first aspect, connecting the one or more first HMHC blocks to the device includes controlling respective heat switches connected between the one or more first HMHC blocks and the device to connect the one or more first HMHC blocks to the device, wherein disconnecting the one or more first HMHC blocks from the device includes controlling the respective heat switches connected between the one or more first HMHC blocks and the device to disconnect the one or more first HMHC blocks from the device, and wherein connecting the one or more second HMHC blocks to the device includes controlling respective heat switches connected between the one or more second HMHC blocks and the device to connect the one or more second HMHC blocks to the device.

In a second aspect, alone or in combination with the first aspect, process 500 includes disconnecting, at the first time, the one or more first HMHC blocks from the second cooling circuit, reconnecting, at the second time, the one or more first HMHC blocks to the second cooling circuit, and disconnecting, at the second time, the one or more second HMHC blocks from the second cooling circuit.

In a third aspect, alone or in combination with one or more of the first and second aspects, disconnecting the one or more first HMHC blocks from the second cooling circuit includes controlling respective heat switches connected between the one or more first HMHC blocks and the second cooling circuit to disconnect the one or more first HMHC blocks from the second cooling circuit, wherein reconnecting the one or more first HMHC blocks to the second cooling circuit includes controlling the respective heat switches connected between the one or more first HMHC blocks and the second cooling circuit to connect the one or more first HMHC blocks to the second cooling circuit, and wherein disconnecting the one or more second HMHC blocks from the second cooling circuit includes controlling respective heat switches connected between the one or more second HMHC blocks and the second cooling circuit to disconnect the one or more second HMHC blocks from the second cooling circuit.

In a fourth aspect, alone or in combination with one or more of the first through third aspects, process 500 includes disconnecting, at a third time, the one or more second HMHC blocks from the device, and connecting, at the third time, one or more third HMHC blocks, of the plurality of HMHC blocks, to the device to manipulate the cooling of the device.

In a fifth aspect, alone or in combination with one or more of the first through fourth aspects, process 500 includes disconnecting, at a third time, the one or more second HMHC blocks from the device, and reconnecting, at the third time, the one or more first HMHC blocks to the device to manipulate the cooling of the device.

In a sixth aspect, alone or in combination with one or more of the first through fifth aspects, disconnecting the one or more first HMHC blocks from the device and connecting the one or more second HMHC blocks to the device are based on equilibration, within a threshold, of temperatures of the one or more first HMHC blocks and a temperature of the device.

In a seventh aspect, alone or in combination with one or more of the first through sixth aspects, connecting the one or more first HMHC blocks to the device includes connecting the one or more first HMHC blocks to respective regions of the device to generate a first thermal gradient across the device, and connecting the one or more second HMHC blocks to the device includes connecting the one or more second HMHC blocks to respective regions of the device to generate a second thermal gradient across the device.

Although FIG. 5 shows example blocks of process 500, in some implementations, process 500 includes additional blocks, fewer blocks, different blocks, or differently arranged blocks than those depicted in FIG. 5. Additionally, or alternatively, two or more of the blocks of process 500 may be performed in parallel.

The foregoing disclosure provides illustration and description, but is not intended to be exhaustive or to limit the implementations described herein to the precise forms that are described. Modifications and variations can be made in light of the above description or may be acquired from practice of the implementations described herein.

As used herein, the term “component” is intended to be broadly construed as hardware, firmware, and/or a combination of hardware and software. It will be apparent that systems and/or methods described herein can be implemented in different forms of hardware, firmware, or a combination of hardware and software. The actual specialized control hardware or software code used to implement these systems and/or methods is not limiting of the implementations described herein. Thus, the operation and behavior of the systems and/or methods are described herein without reference to specific software code—it being understood that software and hardware can be designed to implement the systems and/or methods based on the description herein.

As used herein, satisfying a threshold may, depending on the context, refer to a value being greater than the threshold, greater than or equal to the threshold, less than the threshold, less than or equal to the threshold, equal to the threshold, not equal to the threshold, or the like.

Even though particular combinations of features are recited in the claims and/or described in the specification, these combinations are not intended to limit the implementations described herein. In fact, many of these features can be combined in ways not specifically recited in the claims and/or described in the specification. For example, the description includes each dependent claim in combination with every other claim in the claim set. As used herein, a phrase referring to “at least one of” a list of items refers to any combination of those items, including single members. As an example, “at least one of: a, b, or c” is intended to cover a, b, c, a-b, a-c, b-c, and a-b-c, as well as any combination with multiple of the same item.

When “a component” or “one or more components” (or another element, such as “a processor” or “one or more processors”) is described or claimed (within a single claim or across multiple claims) as performing multiple operations or being configured to perform multiple operations, this language is intended to broadly cover a variety of architectures and environments. For example, unless explicitly claimed otherwise (e.g., via the use of “first component” and “second component” or other language that differentiates components in the claims), this language is intended to cover a single component performing or being configured to perform all of the operations, a group of components collectively performing or being configured to perform all of the operations, a first component performing or being configured to perform a first operation and a second component performing or being configured to perform a second operation, or any combination of components performing or being configured to perform the operations. For example, when a claim has the form “one or more components configured to: perform X; perform Y; and perform Z,” that claim should be interpreted to mean “one or more components configured to perform X; one or more (possibly different) components configured to perform Y; and one or more (also possibly different) components configured to perform Z.”

No element, act, or instruction used herein should be construed as critical or essential unless explicitly described as such. Also, as used herein, the articles “a” and “an” are intended to include one or more items, and can be used interchangeably with “one or more.” Further, as used herein, the article “the” is intended to include one or more items referenced in connection with the article “the” and can be used interchangeably with “the one or more.” Furthermore, as used herein, the term “set” is intended to include one or more items (e.g., related items, unrelated items, or a combination of related and unrelated items,), and can be used interchangeably with “one or more.” Where only one item is intended, the phrase “only one” or similar language is used. Also, as used herein, the terms “has,” “have,” “having,” or the like are intended to be open-ended terms. Further, the phrase “based on” is intended to mean “based, at least in part, on” unless explicitly stated otherwise. Also, as used herein, the term “or” is intended to be inclusive when used in a series and can be used interchangeably with “and/or,” unless explicitly stated otherwise (e.g., if used in combination with “either” or “only one of”).

What is claimed is:

1. A cryogenic cooling system, comprising:
a device;
a first cooling circuit thermally connected to the device and configured to perform cooling of the device;
a second cooling circuit;
a plurality of high mass-heat capacity (HMHC) blocks;
a first set of heat switches configured to thermally connect the plurality of HMHC blocks to the device and to thermally disconnect the plurality of HMHC blocks from the device; and
a second set of heat switches configured to thermally connect the plurality of HMHC blocks to the second cooling circuit and to thermally disconnect the plurality of HMHC blocks from the second cooling circuit.

2. The cryogenic cooling system of claim 1, wherein the first set of heat switches comprises first heat switches connected to respective HMHC blocks of the plurality of HMHC blocks, and wherein the second set of heat switches comprises second heat switches connected to respective HMHC blocks of the plurality of HMHC blocks.

3. The cryogenic cooling system of claim 2, wherein each first heat switch is configured to selectively thermally connect the respective HMHC block to the device to manipulate the cooling of the device, and wherein each second heat switch is configured to selectively thermally connect the respective HMHC block to the second cooling circuit to cool the HMHC block.

4. The cryogenic cooling system of claim 1, further comprising:
a thermally conductive material connecting the device and the first set of heat switches.

5. The cryogenic cooling system of claim 4, wherein the first cooling circuit is connected to a first surface of the device, and the thermally conductive material is connected to a second surface of the device.

6. The cryogenic cooling system of claim 1, further comprising:
a plurality of thermally conductive material segments, each connecting a respective heat switch of the first set of heat switches and a region of the device.

7. The cryogenic cooling system of claim 6, wherein each heat switch, of the first set of heat switches, is configured to selectively thermally connect a respective HMHC block, of the plurality of HMHC blocks, to a region of the device via a thermally conductive material segment, of the plurality of thermally conductive material segments, to manipulate cooling of the region of the device.

8. The cryogenic cooling system of claim 6, wherein the first cooling circuit is connected to a first surface of the device, and the plurality of thermally conductive material segments are connected at respective regions along a second surface of the device.

9. The cryogenic cooling system of claim 6, wherein the first cooling circuit and the plurality of thermally conductive material segments are connected at respective regions along a first surface of the device.

10. The cryogenic cooling system of claim 1, further comprising:
a controller configured to:
control the first set of heat switches to thermally connect or disconnect respective HMHC blocks, of the plurality of HMHC blocks, to or from the device, and
control the second set of heat switches to thermally connect or disconnect respective HMHC blocks, of the plurality of HMHC blocks, to or from the second cooling circuit.

11. The cryogenic cooling system of claim 10, wherein the controller is configured to:
control the first set of heat switches and the second set of heat switches such that one or more HMHC blocks, of the plurality of HMHC blocks, are in an active state in which the one or more HMHC blocks are thermally connected to the device and thermally disconnected from the second cooling circuit, while remaining HMHC blocks, of the plurality of HMHC blocks, are in an inactive state in which the remaining HMHC blocks are thermally disconnected from the device and thermally connected to the second cooling circuit, and
control the first set of heat switches and the second set of heat switches to cycle which of the plurality of HMHC blocks are in the active state.

12. A method of cryogenic cooling, comprising:
performing, by a first cooling circuit, cooling of a device;
connecting a plurality of high mass-heat capacity (HMHC) blocks to a second cooling circuit to cool the plurality of HMHC blocks;
connecting, at a first time, one or more first HMHC blocks to the device to manipulate the cooling of the device;
disconnecting, at a second time, the one or more first HMHC blocks from the device; and
connecting, at the second time, one or more second HMHC blocks, of the plurality of HMHC blocks, to the device to manipulate the cooling of the device.

13. The method of claim 12, wherein connecting the one or more first HMHC blocks to the device comprises controlling respective heat switches connected between the one or more first HMHC blocks and the device to connect the one or more first HMHC blocks to the device;
wherein disconnecting the one or more first HMHC blocks from the device comprises controlling the respective heat switches connected between the one or more first HMHC blocks and the device to disconnect the one or more first HMHC blocks from the device; and
wherein connecting the one or more second HMHC blocks to the device comprises controlling respective heat switches connected between the one or more second HMHC blocks and the device to connect the one or more second HMHC blocks to the device.

14. The method of claim 12, further comprising:
disconnecting, at the first time, the one or more first HMHC blocks from the second cooling circuit;
reconnecting, at the second time, the one or more first HMHC blocks to the second cooling circuit; and
disconnecting, at the second time, the one or more second HMHC blocks from the second cooling circuit.

15. The method of claim 14, wherein disconnecting the one or more first HMHC blocks from the second cooling circuit comprises controlling respective heat switches connected between the one or more first HMHC blocks and the second cooling circuit to disconnect the one or more first HMHC blocks from the second cooling circuit;
wherein reconnecting the one or more first HMHC blocks to the second cooling circuit comprises controlling the respective heat switches connected between the one or more first HMHC blocks and the second cooling circuit to connect the one or more first HMHC blocks to the second cooling circuit; and
wherein disconnecting the one or more second HMHC blocks from the second cooling circuit comprises controlling respective heat switches connected between the one or more second HMHC blocks and the second cooling circuit to disconnect the one or more second HMHC blocks from the second cooling circuit.

16. The method of claim 12, further comprising:
disconnecting, at a third time, the one or more second HMHC blocks from the device; and
connecting, at the third time, one or more third HMHC blocks, of the plurality of HMHC blocks, to the device to manipulate the cooling of the device.

17. The method of claim 12, further comprising:
disconnecting, at a third time, the one or more second HMHC blocks from the device; and
reconnecting, at the third time, the one or more first HMHC blocks to the device to manipulate the cooling of the device.

18. The method of claim 12, wherein disconnecting the one or more first HMHC blocks from the device and connecting the one or more second HMHC blocks to the device are based on equilibration, within a threshold, of temperatures of the one or more first HMHC blocks and a temperature of the device.

19. The method of claim 12, wherein connecting the one or more first HMHC blocks to the device comprises connecting the one or more first HMHC blocks to respective regions of the device to generate a first thermal gradient across the device; and
wherein connecting the one or more second HMHC blocks to the device comprises connecting the one or more second HMHC blocks to respective regions of the device to generate a second thermal gradient across the device.

20. A cryogenic cooling system, comprising:
a first cooling circuit thermally connectable to a device and configured to perform cooling of the device;
a second cooling circuit;
a plurality of cryogenic heat sinks thermally connectable to the device via respective first heat switches, and thermally connectable to the second cooling circuit via respective second heat switches; and
a controller configured to:
control the respective first heat switches and the respective second heat switches such that one or more cryogenic heat sinks, of the plurality of cryogenic heat sinks, are in an active state in which the one or more cryogenic heat sinks are thermally connected to the device and disconnected from the second cooling circuit, and one or more other cryogenic heat sinks, of the plurality of cryogenic heat sinks, are in an inactive state in which the one or more other cryogenic heat sinks are thermally disconnected from the device and connected to the second cooling circuit, and
control the respective first heat switches and the respective second heat switches to rotate which of the plurality of cryogenic heat sinks are in the active state and which of the plurality of cryogenic heat sinks are in the inactive state.
